(19) United States
(12) Patent Application Publication
(10) Pub. No.: US 2026/0303134 A1
(43) Pub. Date: Oct. 1, 2026

(54) Methods and Apparatus for Linearization of a Power Amplifier Output

(71) Applicant: Telefonaktiebolaget LM Ericsson (publ), Stockholm (SE)

(72) Inventors: Anahid Safavi, Bromma (SE); Hamed Farhadi, Stockholm (SE); Jing Liu, Täby (SE); Junfeng Jie, Beijing (CN)

(21) Appl. No.: 19/478,234

(22) PCT Filed: Apr. 27, 2023
(86) PCT No.: PCT/CN2023/091063

§ 371 Date: Oct. 23, 2025

(51) Int. Cl. H04B 1/04; H03F 1/32; H03F 3/213

(52) U.S. Cl. CPC H04B 1/0475; H03F 1/32; H03F 3/213; H04B 2001/0408

(57) ABSTRACT

A method (S300) and apparatus (40) for linearization of a power amplifier (PA) output. The method comprises training (S3A1) a neural network (NN) of an NN-based Digital Pre-Distortion (DPD) unit (51) using a feedback loop. The feedback loop comprises obtaining (S3B1) a training pre-distorter signal, a training PA signal and a training DPD unit signal, calculating (S3B2) a training signal length, calculating (S3B3) a time shifted signal, calculating (S3B4) a phase mismatch between the time shifted signal and the training DPD unit signal, calculating (S3B5) a compensated pre-distorter signal using the training pre-distorter signal and the phase mismatch, and training (S3B6) the NN of the NN-based DPD unit (51) using the compensated pre-distorter signal. The method further comprises inputting a signal to be amplified into the NN-based DPD unit (51) to obtain a DPD unit signal that is input into the PA (53), and obtaining an amplified signal from the PA (53).

### TECHNICAL FIELD

Embodiments of the present disclosure relate to methods and apparatus in communication networks, and particularly methods and apparatus for linearization of a power amplifier output in a communication network.

### BACKGROUND

A Digital Pre-Distortion (DPD) Unit is used to compensate for power amplifier (PA) non-linearity, for example in high output power regions. A DPD unit may be used to perform linearization of the PA output, for example by amplifying the inverse transfer function of the PA such that the transfer function of the cascade of the DPD and PA remains linear.

Neural networks (NN) are able to model complex non-linearities, and therefore may be considered as promising candidates to be used for linearization. Although multiple varieties of NN are available, feed forward NNs are the most studied networks for linearization purposes due to their relatively low complexity and rapid convergence.

Feed forward NNs may comprise a sequential layer of function composition. Each layer may output a set of vectors that server as inputs to the next layer, which may be a set of functions. Forward feed NNs may comprise three types of layers: input layers, hidden layers, and output layers. Input layers are layers of the NN into which raw data is input. Hidden layers form sequences of functions or sets of functions to which either raw inputs or outputs of previously hidden layers are applied. Output layers form final functions or sets of functions of the NN.

A prior art feed forward NN is depicted in FIG. 1. Off-the-shelf feed forward NNs may be customised in the input by considering additional memory elements to assist in modelling of physical behaviours of a power amplifier, for example memory effects. In order to consider memory effects of the PA, the input layer of the NN may be fed by both the current inputs and the inputs at a previous time instance. For example, as shown in FIG. 1 the inputs to the input layer of the NN may include a memory term in order to encompass the inputs at a previous time instance (each term characterised by a delay of 0, 1, . . . m), with each memory term having a corresponding delay element z⁻¹.

Manual reconfiguration or software/hardware tools may be required for selection of memory terms. In general, when a power amplifier suffers dominant memory impact (that is, when very large bandwidth is used e.g., 6G), using more memory terms is beneficial. Adding envelop terms is beneficial when both non-linearity and memory impacts are present.

Residual neural networks are NNs that have paths that skip at least one layer (for example, a hidden layer) of the NN. Residual Real-Valued Time Delay Neural Networks (R2TDNN) are a type of residual NN which may learn the non-linear behaviour of a PA or DPD by using a direct input/output connection such as an Identity Connection, as shown in FIG. 1.

As shown in FIG. 1, the inputs to the input layer of the NN may also include an envelop term. Adding envelop terms to the input of the input layer may bring some additional enhancements by improving the capability of neural networks to mimic better the non-linearity of a PA. Networks utilizing an envelop term may also be referred to as Residual Augmented Real Valued Time Delay Neural Networks (Res-ARVTDNN).

A Non-Residual Neural Networks (NResNN) is a non-residual version of a feed forward neural networks which is extended with memory terms. A Non-Residual Augmented Real Valued Time Delay Neural Network (Non-Residual ARVTDNN) is a feed-forward neural network with envelop terms and memory terms included, without residual connections.

Potential feed forward NNs for PA linearization are summarised in Table 1, along with related characteristics. The “X” sign indicates the inclusion of the associated feature in the neural network.

TABLE 1
Feed Forward NNs and Associated Characteristics

| | | | Residual |
|---|---|---|---|
| Network | Memory term | Envelop term | connection |
| Res-ARVTDNN | X | X | X |
| R2TDNN | X | | X |
| NResNN | X | | |
| Non-residual ARVTDNN | X | X | |

A NN-based DPD may use indirect learning approach (ILA) for training. Training that utilises and indirect learning approach may estimate the DPD parameters indirectly by using an inverse structure. This training technique is based on the theory of p^{th} order inverses of non-linear system, and more specifically that the p^{th} order pre-inverse of a system is identical to its p^{th} order post-inverse. As the power amplifier may create non-linear components and these non-linear components are not dominant components of the power amplifier (PA), this technique may be reused in DPD design.

FIG. 2 depicts a neural network based DPD system. The system comprises a DPD unit 201, which may be a NN-based DPD unit and has a DPD input signal (x). The system further comprises a PA 202 and a post-inverse model 203. The DPD unit may be configured to input directly into the PA such that the output of the DPD unit is a PA input signal (z). Alternatively, a filter may be present between the DPD unit and the PA such that the PA input signal is the filtered DPD output signal. The PA may have an associated PA output signal (y), and the PA may be configured to input directly into the post-inverse model 203. Alternatively, the PA output signal (y) may be filtered or processed before being input to the post-inverse model.

In the system of FIG. 2, an inverse PA neural network model, also known as post-distorter/post-inverse model 203, may be trained using the PA output signal (y) as input and PA input signal (z) as output. Once the post-inverse or post distorter model is identified, the coefficients generated during the training process may then be copied to an identical neural network-based model, which is referred to as the pre-distorter model or DPD unit 201. One way to estimate the post-inverse coefficients of the power amplifier described above is to minimize an error signal (204) between input and output of power amplifier. In the system of FIG. 2 which comprises an error signal (204), the goal of the system is to minimize the error signal to get the coefficients. An alternative way that is not depicted in FIG. 2 is to instead use input and output of power amplifier in modelling the post-inverse. The arrow sign of FIG. 2 indicates the copying of the obtained coefficients to the post-inverse in order to be used in further steps (for example as detailed below).

Once the DPD neural network-based model coefficients are in place, the output of the DPD unit 201 may be predicted given the DPD model coefficients and its input. The output of the DPD unit 201 is then used as the input to the PA 202. The linearization performance of the cascade of the DPD unit 201 and PA 202 are measured as the Normalized Mean Square Error (NMSE) error measured between the PA output signal (which may be a PA gain compensated output signal) and the DPD input signal (x).

Accordingly, the indirect learning algorithm when one iteration is used may be summarized as in the following:
1. The post-inverse model is a predefined model trained using z¹=x¹ and y¹, with z¹ denoting the z in the first iteration;
2. The post-inverse model coefficients are copied to DPD once the training is finished;
3. Given x and the existing DPD model, predict z (and, in specific examples, additionally predict y, given z).

Accordingly, in the above process feedback information from the output of the power amplifier (y) is used to find DPD coefficients.

Self-recovery is an automatic recovery mechanism that may be triggered when a fault is detected or when the accuracy of the cascade of the DPD unit and PA falls below an acceptable level or threshold. A fault or a deviation from normal behaviour in the feedforward or feedback circuit related to PA may trigger re-training occasions for the cascade of DPD and PA, for example to adjust the transmission chain to the power amplifier input characteristics.

Similarly, a detection that the accuracy of the cascade of the DPD unit and PA falls below an acceptable level or threshold may trigger re-training occasions for the cascade of DPD and PA.

However, prior NN solutions used in digital predistortion to linearize the power amplifier response do not consider in the feedback loop any circuit to adjust or compensate for the potential mismatches that occur within the power amplifier (that is, in between power amplifier input and output). These mismatches include time mismatches and phase mismatches created between the input and output of the power amplifier, due to the potential usage of filters, oscillators, and mixers within the PA. If these mismatches are not compensated, the linearization performance/complexity and ultimately the throughput of the system may be impacted, resulting in decreased system accuracy.

Furthermore, prior NN solutions used for linearization do not consider aspects of non-linearization that occur outside the cascade of the DPD unit and PA, for example digital filters to separate and treat multiple bands of the wideband signals. This may lead to poor performance of the linearization algorithm. This ultimately would impact the throughput that is expected from wideband operation.

Additionally, regarding re-training of a DPD unit, prior solutions may start re-training process from the beginning using incoming data. This reduces the efficiency of the re-training process, as the previously trained model is lost once re-training has begun. Further, different training occasions may not be associated together. For instance, re-training due to a self-recovery or fault handling may be triggered separately from re-training required for the compensation of detected mismatch. This may require having dedicated circuits of control/supervision circuits and fault handling circuits, which may be difficult to maintain. Neural network-based or machine learning based solutions offer the flexibility of low complexity online re-training by allowing to refine already trained model to obtain optimal or close to optimal learning weights from existing ones. In this sense, they offer a flexibility and/or lower computational complexity compared to the existing solutions.

### SUMMARY

It is an object of the present disclosure to facilitate linearization of a power amplifier output, for example in communication networks.

Embodiments of the disclosure aim to provide apparatuses and methods that alleviate some or all of the problems identified.

An embodiment of the disclosure provides a method for linearization of a power amplifier (PA) output. The method comprises training a neural network (NN) of an NN-based Digital Pre-Distortion (DPD) unit using a feedback loop. The feedback loop comprises obtaining a training pre-distorter signal, a training PA signal and a training DPD unit signal, wherein the training pre-distorter signal, the training PA signal, and the training DPD unit signal are all associated with each other. The feedback loop further comprises calculating a training signal length using the training PA signal and the training DPD unit signal. The feedback loop further comprises calculating a time shifted signal using the training PA signal and the training signal length. The feedback loop further comprises calculating a phase mismatch between the time shifted signal and the training DPD unit signal. The feedback loop further comprises calculating a compensated pre-distorter signal using the training pre-distorter signal and the phase mismatch, and training the NN of the NN-based DPD unit using the compensated pre-distorter signal. The method further comprises inputting a signal to be amplified into the NN-based DPD unit, obtaining a DPD unit signal from the NN-based DPD unit, inputting the DPD unit signal into the PA, and obtaining an amplified signal from the PA.

A further embodiment of the disclosure provides a network apparatus. The network apparatus comprises processing circuitry and a non-transitory machine-readable medium storing instructions. The network apparatus is configured to train a neural network, NN, of an NN-based Digital Pre-Distortion, DPD, unit using a feedback loop. The feedback loop comprises obtaining a training pre-distorter signal, a training PA signal and a training DPD unit signal, wherein the training pre-distorter signal, the training PA signal, and the training DPD unit signal are all associated with each other. The feedback loop further comprises calculating a training signal length using the training PA signal and the training DPD unit signal. The feedback loop further comprises calculating a time shifted signal using the training PA signal and the training signal length. The feedback loop further comprises calculating a phase mismatch between the time shifted signal and the training DPD unit signal. The feedback loop further comprises calculating a compensated pre-distorter signal using the training pre-distorter signal and the phase mismatch, and training the NN of the NN-based DPD unit using the compensated pre-distorter signal. The network apparatus is further configured to: input a signal to be amplified into the NN-based DPD unit, obtain a DPD unit signal from the NN-based DPD unit, input the DPD unit signal into the PA, and obtain an amplified signal from the PA.

Further embodiments provide methods, network nodes and systems as discussed herein.

### BRIEF DESCRIPTION OF DRAWINGS

For a better understanding of the present disclosure, and to show how it may be put into effect, reference will now be made, by way of example only, to the accompanying drawings, in which:

FIG. 1 is a diagram presenting an overview of a feed forward neural network;

FIG. 2 is a schematic diagram of a NN-based DPD;

FIG. 3A and FIG. 3B (collectively referred to as FIG. 3) are flowcharts of a method for linearization of a PA output, in accordance with embodiments;

FIG. 4A and FIG. 4B (collectively referred to as FIG. 4) are schematic diagrams of a network node, in accordance with embodiments;

FIG. 5 is a schematic diagram of a system, in accordance with embodiments;

FIG. 6 is a flowchart of a method of training a NN-based DPD, in accordance with embodiments;

FIG. 7 is a diagram presenting an overview of a feed forward neural network, in accordance with embodiments;

FIG. 8 is a signal diagram of a system, in accordance with embodiments;

FIG. 9 is a plot of results of a first simulation, in accordance with embodiments;

FIG. 10 is a plot of results of a second simulation, in accordance with embodiments;

FIG. 11 is a plot of results of a third simulation, in accordance with embodiments;

FIG. 12 is a plot of results of a fourth simulation, in accordance with embodiments; and

FIG. 13 is a plot of results of a fifth simulation, in accordance with embodiments.

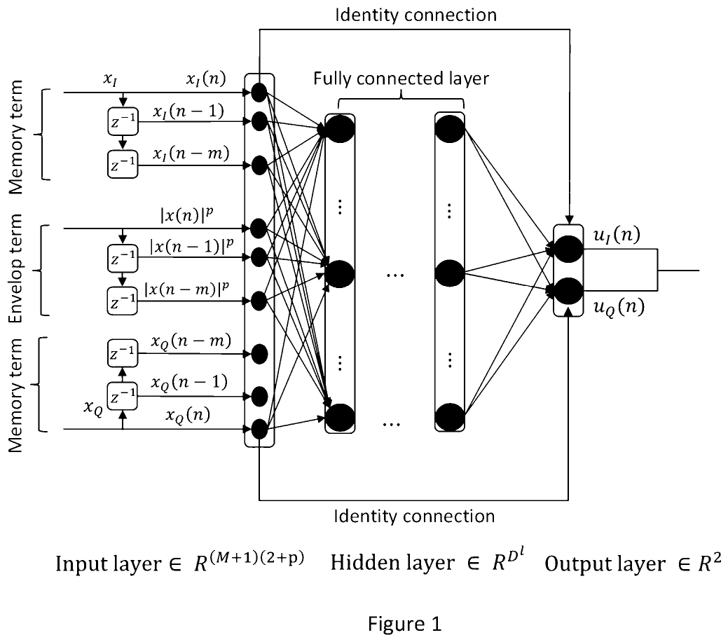

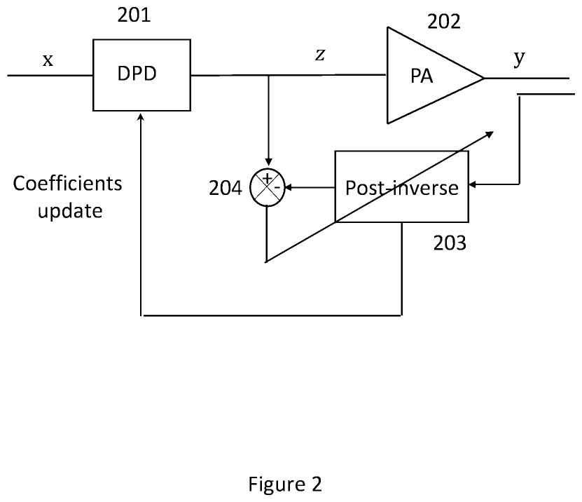

### DETAILED DESCRIPTION

For the purpose of explanation, details are set forth in the following description in order to provide a thorough understanding of the embodiments disclosed. It will be apparent, however, to those skilled in the art that the embodiments may be implemented without these specific details or with an equivalent arrangement.

The following sets forth specific details, such as particular embodiments for purposes of explanation and not limitation. It will be appreciated by one skilled in the art that other embodiments may be employed apart from these specific details. In some instances, detailed descriptions of well-known methods, nodes, interfaces, circuits, and devices are omitted so as to not obscure the description with unnecessary detail. Those skilled in the art will appreciate that the functions described may be implemented in one or more nodes using hardware circuitry (e.g., analog and/or discrete logic gates interconnected to perform a specialized function, ASICs, PLAs, etc.) and/or using software programs and data in conjunction with one or more digital microprocessors or general purpose computers that are specially adapted to carry out the processing disclosed herein, based on the execution of such programs. Nodes that communicate using the air interface also have suitable radio communications circuitry. Moreover, the technology may additionally be considered to be embodied entirely within any form of computer-readable memory, such as solid-state memory, magnetic disk, or optical disk containing an appropriate set of computer instructions that would cause a processor to carry out the techniques described herein.

Hardware implementation may include or encompass, without limitation, digital signal processor (DSP) hardware, a reduced instruction set processor, hardware (e.g., digital or analog) circuitry including but not limited to application specific integrated circuit(s) (ASIC) and/or field programmable gate array(s) (FPGA(s)), and (where appropriate) state machines capable of performing such functions.

In terms of computer implementation, a computer is generally understood to comprise one or more processors, one or more processing modules or one or more controllers, and the terms computer, processor, processing module and controller may be employed interchangeably. When provided by a computer, processor, or controller, the functions may be provided by a single dedicated computer or processor or controller, by a single shared computer or processor or controller, or by a plurality of individual computers or processors or controllers, some of which may be shared or distributed. Moreover, the term “processor” or “controller” also refers to other hardware capable of performing such functions and/or executing software, such as the example hardware recited above.

Aspects of the present disclosure may provide for digital pre-distortion of a transmit signal using a feedback signal from power amplifier's output to compensate the mismatch between the input and output of the power amplifier. Accordingly, aspects of the present disclosure may provide one or more of the following:
the mismatch includes but is not limited to time mismatch and phase mismatch;
the digital pre-distortion may be implemented using e.g. a neural network;
the compensation may be performed based on offline or online measurements;
the pre distorter is trained/re-trained using the compensated inputs of the power amplifier;
the compensation is applied at the transmit signal after re-training of pre-distorter;
the re-training is triggered when the mismatches become larger than a given threshold;
the re-training is triggered during the self-recovery; and/or
the re-training re-uses previously trained coefficients.

Further, when the signal to be amplified (or transmit signal) is an uplink signal and when digital pre distorter is used in user equipment, a dedicated signalling method may be needed. Accordingly, when the transmit signal/signal to be amplified is an uplink signal and when digital pre distorter is used in the user equipment, a new signalling scheme may take place to implement aspects of the present disclosure.

Prior neural network-based solutions mentioned for linearization do not consider the feedback loop from output of power amplifier to compensate for potential time and phase mismatch. Additionally, feedback loops that are used for non-neural network-based solutions may not be adapted to neural network-based solutions without modification, and the adaptation of those feedback methods to the neural network-based solutions is not straight forward due to the non-linearity of the NN model. That is, due to non-linearity and the presence of hidden layers in the neural network-based solutions it is not straight forward to separate the linearization module to weighted sum of nonlinear functions and consider weights separately. More precisely, as the neural networks are highly non-linear, finding similarities within neural network-based linearization module or conventional linearization is not straight forward.

Accordingly, neural network-based solutions used for linearization with feedback from output to input of power amplifier may provide better linearization performance obtained with lower computational complexity. This leads ultimately to a system that may perform with higher throughput. For example, more than 2 dB of performance improvement (in terms of NMSE) may be obtained when using time alignment. Better NMSE may enable the system to work with higher back-off thus increasing ultimately the throughput. That is, when time alignment is applied the computational complexity may be reduced without scarifying the performance. For instance, for a NMSE of −37.5 dB the computational complexity may be reduced from 300 to 80 flops.

Processing wideband signals may also require the use of additional digital filters to limit the bandwidth of the wideband signals. The positioning of these filters may vary, providing varying impacts and/or mismatches on the PA linearization process.

Training and re-training of a neural network may offer more flexibility compared to non-neural network-based solutions. Indeed, different training occasions such as self-recovery and regular re-training may be combined in a single re-training attempt, and thus may reduce the need for frequent re-training and reduce the complexity of the training process. Accordingly, combining different re-training occasions for self-recovery and regular re-training may result in only requiring a single controller to manage all re-training processes.

Additionally, re-training may re-use already existing weights obtained previously from offline training, this requiring fewer training iterations with a low learning rate to obtain new suitable weights. This may reduce the complexity and the time needed for re-training. That is, contrary to conventional training used for non-neural network-based solutions, the re-training is not initiated from the beginning; the re-training starts with the pre-defined weights of the previously trained neural network instead of a random guess, and accordingly a smaller number of iterations may be enough to converge towards the final state.

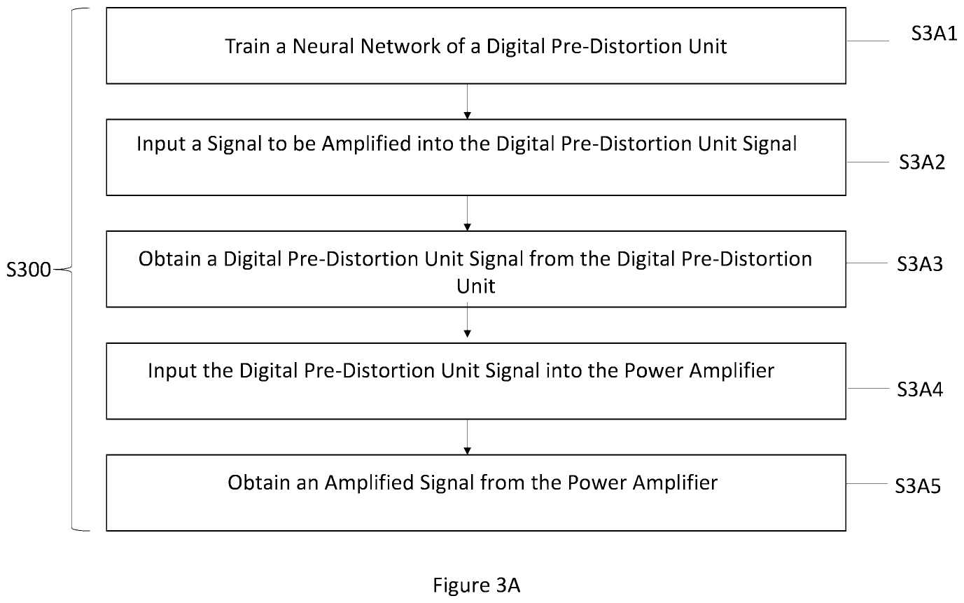

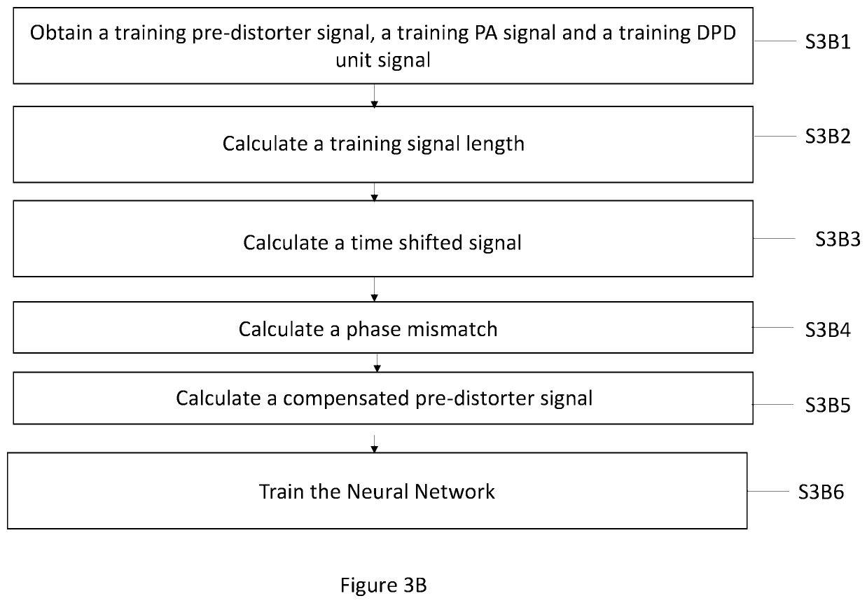

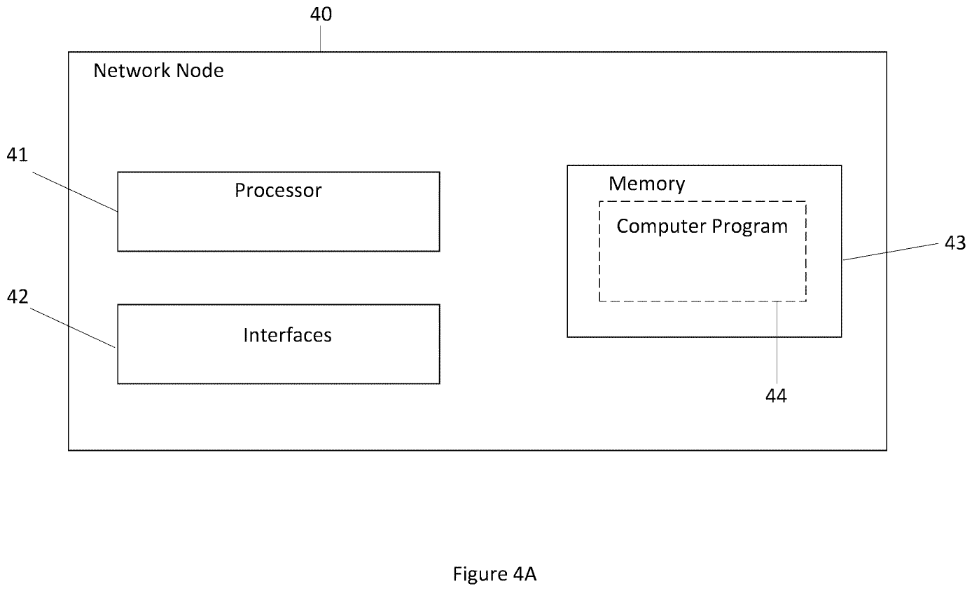

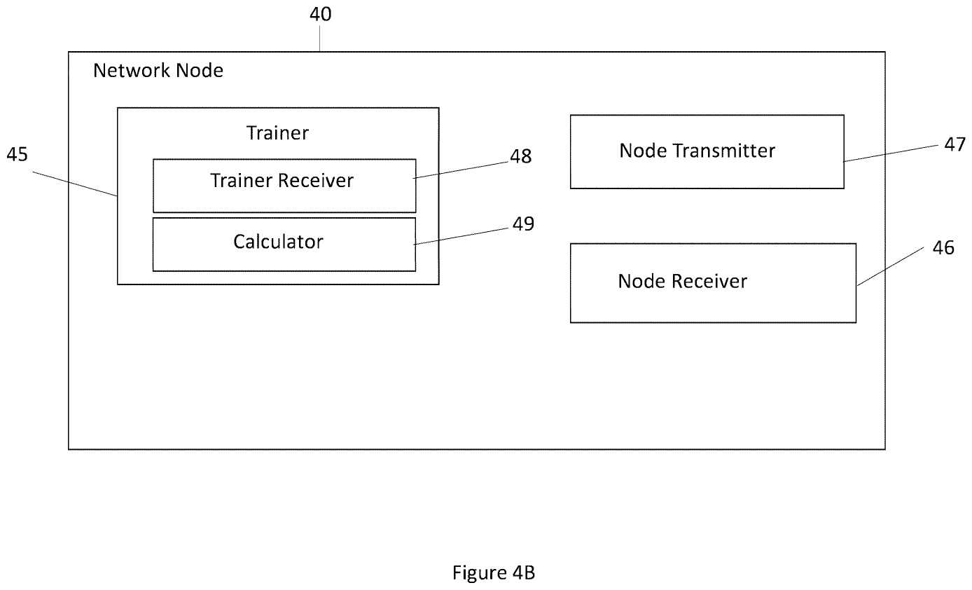

A method in accordance with embodiments is illustrated in FIG. 3, which is a flowchart showing a method for linearization of a PA output. The method may be performed by any suitable apparatus, for example a network node. An example of a suitable network node is depicted in FIG. 4.

As depicted in FIG. 4A, the network node 40 may comprise a processor 41, interfaces 42, and a memory 43 storing a computer program 44. The steps of the method, for example as depicted in FIG. 3, may be performed in accordance with the computer program 44 stored in the memory 43, and may be executed by the processor 41 in conjunction with one or more interfaces 42.

As depicted in FIG. 4B, the method step of training a NN of an NN-based DPD unit using a feedback loop may be performed by a trainer 45 of the network node 40. Specifically, the method step of obtaining a training pre-distorter signal, a training PA signal and a training DPD unit signal may be performed by a trainer receiver 48 of the trainer 45. The method step of calculating a training signal length between using the training PA signal and the training DPD unit signal may be performed by a calculator 49 of the trainer 45. The method step of calculating a time shifted signal using the training PA signal and the training signal length may be performed by a calculator 49 of the trainer 45. The method step of calculating a phase mismatch between the time shifted signal and the training DPD unit signal may be performed by a calculator 49 of the trainer 45. The method step of calculating a compensated pre-distorter signal using the training pre-distorter signal and the phase mismatch may be performed by a calculator 49 of the trainer 45. The step of training the NN of the NN-based DPD unit using the compensated pre-distorter signal may be performed by the trainer 45 of the network node 40.

The method step of inputting a signal to be amplified into the NN-based DPD unit may be performed by the node transmitter 47 of the network node 40. The method step of obtaining a DPD unit signal from the NN-based DPD unit may be performed by the node receiver 46 of the network node 40. The method step of inputting the DPD unit signal into the PA may be performed by the node transmitter 47 of the network node 40. The method step of obtaining an amplified signal from the PA may be performed by the node receiver 46 of the network node 40.

As shown in Step S3A1 of FIG. 3A, the method (S300) of embodiments comprises training a neural network of a DPD Unit. The steps of training the NN of the DPD Unit are shown in FIG. 3B.

In order to compensate for a time mismatch, training the NN of the DPD Unit may comprise obtaining a training pre-distorter signal, a training PA signal and a training DPD unit signal (Step S3B1), calculating a training signal length (Step S3B2), and calculating a time shifted signal (Step S3B3). The training pre-distorter signal, the training PA signal, and the training DPD unit signal are all associated with each other. The training signal length may be calculated using the training PA signal and the training DPD unit signal. The time shifted signal may be calculated using the training PA signal and the training signal length. Training the NN of the DPD Unit may also comprise calculating a compensated pre-distorter signal (Step S3B5) using the time shifted signal, and training the neural network using the compensated pre-distorter signal (Step S3B6). Training the neural network using the compensated pre-distorter signal may comprise feeding the compensated pre-distorter signal to the NN-DPD unit.

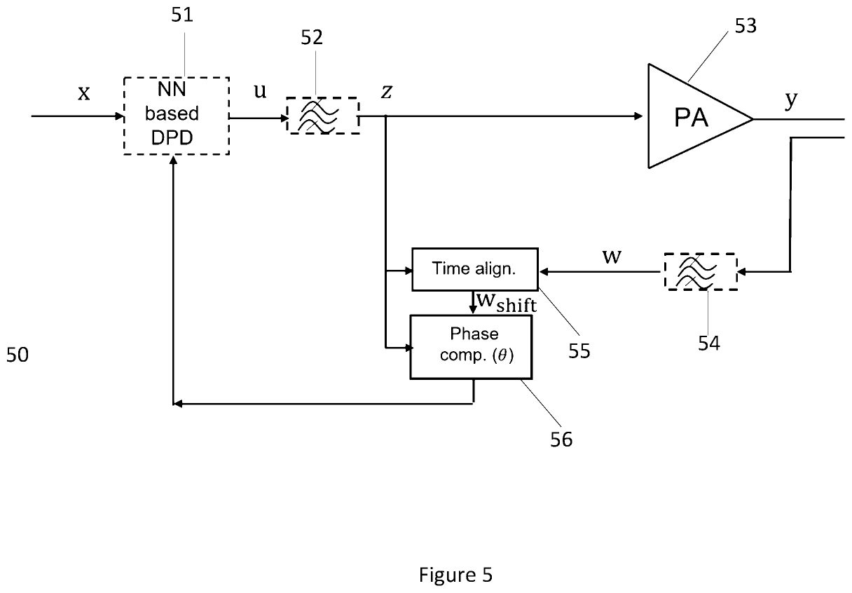

A schematic diagram of a system in accordance with embodiments is shown in FIG. 5. As shown in FIG. 5, the system comprises a feedback loop 50. The feedback loop comprises a time alignment module 55 which may measure and compensate for the time mismatch between the input and output of the power amplifier. Time mismatch may be computed by calculating the cross correlation between the input and output of the power amplifier. The cross correlation may be calculated using the following equation:

$$r = xCorr ( u , y ) = ifft ( fft ( u ) \cdot conj ( fft ( y ) ) )$$

where r is the cross correlation, u is the training DPD unit signal, y is the training PA signal, fft is the fast Fourier transform function, ifft is the inverse fast Fourier transform function, conj is the conjugate function, and · is the dot product function. The above equation uses unfiltered training DPD unit signal (u) and unfiltered training PA signal (y). However, the filtered training DPD unit signal (z) and filtered training PA signal (w) could be used instead of these signals. That is, the unfiltered training DPD unit signal (u) in the above equation could be replaced by the filtered training DPD unit signal (z) and the unfiltered training PA signal (y) in the above equation could be replaced by the filtered training PA signal (w).

xCorr in the above equation denotes the cross correlation operation in between two input signals. Cross correlation is defined as measure of similarity between the training DPD nit signal and the shifted (lagged) copies of the training PA signal as a function of lag.

The training signal length (or length of the signal/sequence of the cross correlation r) may be equal to 2 L−1, with L being the length of the training PA signal and the training DPD unit signal. The length of a sequence is defined as the number of elements in that sequence. The higher the value of cross correlation r for a lag value, the more similar are the sequences for that time lag. It is possible to omit the time index (n) in expression of sequences (for example, z(n) and w(n)) without the loss of generality.

The fft or fast Fourier transform function converts a signal from its original domain (time) to a representation in frequency domain. The inverse fast Fourier transform function or ifft converts a signal from its frequency domain to time domain.

Cross correlation itself may be computed in frequency domain by using fft over filtered input signals with reduced complexity.

Frequency domain filtering of the input and output of power amplifier may bring some advantage to eliminate parts of the spectrum and get ultimately better performance results by dealing with shorter data sets. Filtering bandwidth may be adjusted considering different factors. For instance, it may be beneficial to consider which intermodulation components are of interest to take them within the filtering bandwidth or outside of the bandwidth. One other way to implement filtering is to filter out spectrums lying outside of IBW (Instantaneous bandwidth) and not to consider intermodulation components. Alternatively, for multi band signals each band may be filtered out and treated independently. This represents a pre-processing of data. Once filtering is applied, both training and inference are performed on filtered input. Non-filtered input and output of power amplifier may be considered as well without loss of generality.

Limiting the bandwidth in this way, or performing a pre-processing in the baseband data for both training and inference operation, would limit the size of data set. This may give a better training performance and ultimately better estimation during inference. Additionally, and when multi-band signals are present with enough separation between bands, filtering may separate each band and treat it separately over a smaller data set and enhance the training/inference performance.

Once cross correlation r is computed, the peak of the cross correlation may indicate the point in time when the (filtered) signals of the input and output of the power amplifier are best aligned. This peak of the cross correlation may be calculated using the following equation:

$$Δ = argmax ( r )$$

where Δ is the peak of cross correlation, argmax is a peak value function, and r is the cross correlation. The peak of cross correlation gives an indication on the value of the integer alignment or time adjustment that is needed to compensate for time-delay.

The training signal length may be calculated using the following equation:

$$N = [ length ( r ) - 1 ] / 2$$

where N is the training signal length, r is the cross correlation, and the length function is the number of elements in the cross correlation.

The time shifted signal (or symbol level time adjustment value) may be computed considering the size of correlated signal and the peaks of correlation. Accordingly, a shift coefficient may be calculated using the following equation;

$$s = N + 1 - Δ$$

where s is the shift coefficient, Δ is the peak of cross correlation, and N is the training signal length.

Once the shift coefficient is computed, the PA output signal y (or filtered PA output signal w) may be circularly shifted to compute a time-adjusted output or time shifted signal. The time shifted signal may therefore be computed using the following equation:

$${w}_{shift} = circshift ( y , s )$$

wherein w_{shift} is the time shifted signal, y is the training PA signal, s is the shift coefficient, and the circshift function rotates the elements of the training PA signal by a number of positions equal to the shift coefficient.

The time alignment method steps that are described above form an integer alignment computed on symbol level. Finer time alignment to sub-sample resolution may be considered as well.

In order to compensate for a phase mismatch, training the NN of the DPD Unit may comprise calculating a phase mismatch (Step S3B4), calculating a compensated pre-distorter signal (Step S3B5), and training the neural network using the compensated pre-distorter signal (Step S3B6). Training the neural network using the compensated pre-distorter signal may comprise feeding the compensated pre-distorter signal to the NN-DPD unit.

In order to undertake these steps, training the NN of the DPD unit may comprise obtaining a training pre-distorter signal, a training PA signal, and a training DPD unit signal (Step S3B1), wherein the training pre-distorter signal, the training PA signal, and the training DPD unit signal are all associated with each other.

In an example where time alignment is applied and time shifted input w_{shift} is computed, the phase mismatch θ between (filtered) input of power amplifier may be computed using the following equation:

$$θ = angle ( {u ( n )}^{*} \cdot {w}_{shift} )$$

wherein θ is the phase mismatch, u(n)* is the complex conjugate of the training DPD unit signal, w_{shift} is the time shifted signal, —is the dot product function and angle is the phase angle function for each element of the dot product function. In the above equation, the scaler value angle denotes phase mismatch in radians. 0 is the phase angle in the interval [−π,π] for each element of a complex array. This may alternatively be written as u(n)*×w_{shift}=|u(n)*×w_{shift}|×e^{jθ} with e^{jθ} being the natural exponential function. Although the above equations use unfiltered signals, the filtered equivalents of said signals may also be used. That is, in the above equation the unfiltered training DPD unit signal u(n) may be replaced by the filtered training DPD unit signal z(n).

The obtained phase mismatch θ indicates the phase shift that may be applied to the training DPD unit signal u (or filtered training DPD unit signal z) to get final alignment. The training DPD unit signal may also be considered to be the PA input signal. If the value of phase mismatch is bigger than a threshold, then the input to the pre distorter may be phase adjusted.

In this example, the input to the pre-distorter may be shifted in order to account for this phase mismatch. Accordingly, a compensated pre-distorter signal may be calculated. A generic input into the DPD unit input x(n) may be written in the following format:

$$x ( n ) = {{x}_{r} ( n )}^{*} {e}^{j θ}$$

where xᵣ(n) is the magnitude of x(n), θ is the phase shift, and j=\sqrt{−1}. The compensated pre-distorter signal may therefore be calculated using the following equation:

$$X ( n ) = ( {x}_{I} ( n ) + j {x}_{Q} ( n ) ) {e}^{j θ}$$

where xᵣ(n) is the compensated pre-distorter signal, x_{I}(n) is the real part of the training pre-distorter signal at time n, x_{Q}(n) is the imaginary part of the training pre-distorter signal at time n, θ is the phase shift, and j=\sqrt{−1}.

In one embodiment of the invention, only time adjustment to compensate for time mismatch is applied (and consequently no phase mismatch is applied). The time adjustment value is computed as discussed above. That is, the time shifted signal may be calculated using the following equation:

$${w}_{shift} = circshift ( y , s )$$

In this equation, the unfiltered PA output signal/training PA signal (y) is used however in an example where the PA output signal is filtered, the filtered PA output signal/filtered training PA signal (w) may also be used. The shift coefficient (s) denotes the time adjustment that should be applied to both the signal to be amplified and the PA output signal/training PA signal.

Following indirect learning approach, the training DPD unit signal and the time shifted signal may be used to train the post-inverse model. Once the post-inverse model is trained and the weights are copied to pre-distorter, the input signal to the pre-distorter should be shifted according to the following equation to consider the time adjustment:

$${x}_{n , shift} ( n ) = circshift ( x ( n ) , shift )$$

where x_{n,shift}(n) is the compensated pre-distorter signal.

In this case, the input to the NN-based DPD may be:

$${X}_{I} ( n ) = real ( {x}_{n , shift} ( n ) )$$

$$and$$

$${X}_{Q} ( n ) = imag ( {x}_{n , shift} ( n ) )$$

This time mismatch described above the same to the case where phase mismatch θ is present but it is equal zero.

This approach has the associated benefit of compensation for a PA time mismatch introduced due to PA internal components.

As shown in FIG. 3B, a method (S300) of present embodiments may include inputting a signal to be amplified into the NN-based DPD unit (Step S3A2), obtaining a DPD unit signal from the NN-based DPD unit (Step S3A3), inputting the DPD unit signal into the PA (Step S3A4), and obtaining an amplified signal from the PA (Step S3A5).

In the specific embodiment of FIG. 5, time and phase mismatch between the input and output of power amplifier are measured in the feedback loop between the NN-based DPD 51 and the PA 53. That is, a DPD input signal (x) is input into the NN-based DPD. This signal is then processed by the DPD to produce a DPD output signal (u). The DPD output signal (u) is processed or filtered by a first filter 52 to produce a filtered DPD output signal which is used as a PA input signal (z) that is input to the PA 53. The PA 53 then produces PA output signal (y). The PA output signal (y) is then filtered or processed by a second filter 54 to produce a filtered PA output signal (w). The filtered PA output signal (w) is processed by a time alignment module 55 to produce a time shifted signal (w_{shift}) and/or processed by a phase compensation module 56 to produce a phase shift (θ). The time shifted signal and/or the phase shift are then fed back into the NN-based DPD 51, in order to further train the NN-based DPD.

In the example as depicted in FIG. 5, the (filtered) input and (filtered) output of power amplifier is first time aligned in the time alignment module. In the phase compensation module, the phase difference between time aligned signal and input to power amplifier (θ) is computed. Obtained phase mismatch (0) indicates the phase shift that should be applied to the input signal of power amplifier (z) to get final alignment in phase and time.

The output of power amplifier (y) may be passed through a second filter 54 and the output of the NN-based DPD (u) may be passed through a first filter 52; alternatively, no filters may be used. The first filter 52 and second filter 54 may be band-pass digital filters (shown with dashed line).

The signal obtained from the second filter 54 (w) is called filtered output of power amplifier. The usage of filtering has shown some benefits in term of performance but is not mandatory for the implementation of the solution. Similar filtering operation is applied to the output of the DPD with the same characteristics.

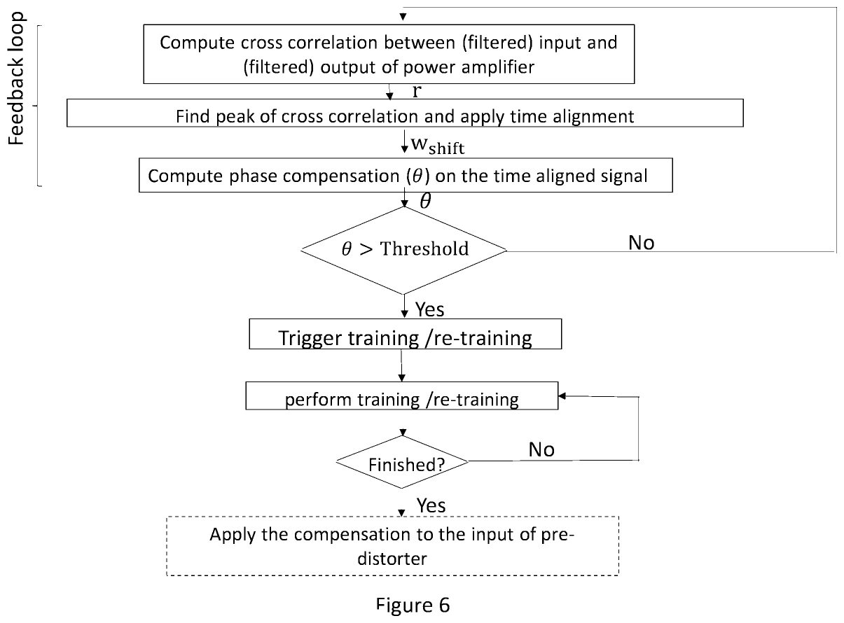

A specific embodiment of training a NN-based DPD is shown in FIG. 6. As shown in FIG. 6, in the feedback loop the cross correlation between the input and output of the PA is computed. Afterwards, peaks of cross correlation are obtained, and a time alignment is computed, and signals are time aligned. Then phase compensation value θ on the time aligned signal is computed. These steps may be performed, for example, as shown in FIG. 3. If the obtained phase compensation is larger than a threshold or if there is a self-recovery signal, then training/re-training of the pre distorter coefficient may be triggered. Once the training is deemed finished, the obtained weights of the pre-distorter are obtained with a consideration of phase alignment. Finally, the obtained phase compensation may be applied to the input signal of the pre-distorter. In some embodiments of the solution, and when there is only time mismatch present, only a time alignment consideration may be applied without calculation of a phase alignment.

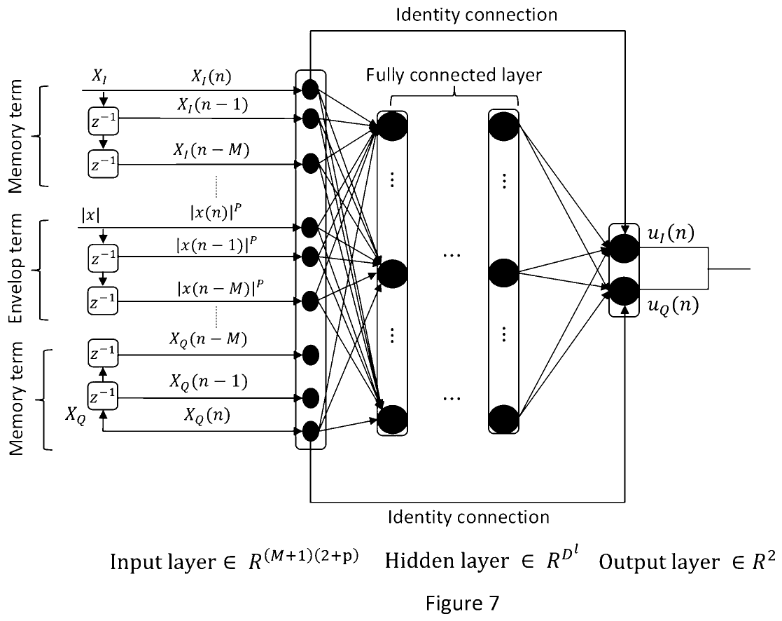

The computed phase is applied to the input of the pre distorter as shown in FIG. 7. In this figure the real and imaginary part of the pre distorter are considering the compensated phase. The envelop term will remain unchanged as there is no phase adjustment to be performed on the envelop term.

As neural networks consider only real valued signal as input, it is possible to separate the real and imaginary part of the input to the neural network using the following equations:

$${X}_{I} ( n ) = real [ ( {x}_{I} ( n ) + j {x}_{Q} ( n ) ) {e}^{j θ} ]$$

$${X}_{I} ( n ) = {x}_{I} ( n ) Cos ( θ ) - {x}_{Q} ( n ) Sin ( θ )$$

$${X}_{Q} ( n ) = imag [ ( {x}_{I} ( n ) + {jx}_{Q} ( n ) ) {e}^{j θ} ]$$

$${X}_{Q} ( n ) = {x}_{Q} ( n ) Cos ( θ ) + {x}_{I} ( n ) Sin ( θ )$$

In the above equations, real and imag of a signal/sequence denotes real and imaginary part of that signal/sequence with j=\sqrt{−1}. FIG. 7 shows the real and imaginary part of the input to the neural networks based DPD once phase adjustment is applied. Additional terms in this figure that account for the envelop of the input signal are shown by |x(n)|, |x(n−1)|, . . . , |x(n)|^{P}, |x(n−1)|^{P}. There is no need to adjust the phase for these terms as the input considers only the envelop term.

In some embodiments, the input to the pre distorter may be time and phase aligned and the weights of the pre-distorter obtained during training operation may be computed using the time/phase aligned signals.

When indirect learning is used, the post-inverse and pre distorter weights, are obtained by using the compensated training DPD unit signal (u or z) and compensated PA output signal (y or w). The compensated signals are used as the output and input of the post-inverse model respectively during the training. The compensated training DPD unit signal is obtained after phase adjustment and may be computed as in the following:

$${z}^{′} ( n ) = z ( n ) {e}^{j θ}$$

where z is the compensated training DPD unit signal, z is the training DPD unit signal, and θ is the phase shift calculated as discussed previously. The compensated training DPD unit signal may also be referred to as the DPD coefficient.

Once the model coefficients for the post inverse model are obtained, the coefficients may be copied to the post inverse model following the indirect learning approach. Accordingly, the input signal to the post inverse model may consider modifications clarified in the input as described above.

In this way, training to obtain the phase adjustment may be done offline and the obtained weights may be considered in the post-inverse or pre-distorter. Training may be computationally expensive in radio, and present embodiments may allow for training to be performed in baseband or over the cloud if delay is not a problem.

Re-training may be needed for several occasions. To reduce the complexity of re-training in terms of number of operations, it is possible to update existing weights from previous training/re-training or a previous measurement on the device (for example, a previous measurement taken in the factory during production). To this end for re-training, it is beneficial to use additional relevant data and apply very low learning rate during a few epochs to obtain new weights. The conventional model-based solution starts for training from the beginning for each re-training instance and uses a random guess as a starting point; thus the re-training technique of present embodiments may converge faster than traditional non-neural network-based solution.

Further, present embodiments may use a single occasion to trigger different training occasions. For example, a single controller may trigger self-recovery and re-training together to reduce the occasions used for re-training specifically when time and phase mismatch are not considerable.

The measurement of the mismatch between input and output of power amplifier may be performed using an off-line process. In such a case, time and phase compensation values may be obtained offline. In some applications, online updating is required for example where the feedback loop and parameter estimation are normally integrated in the system. In this case, time and phase compensation may be done online.

The following is a mathematical derivation showing that considering the phase shift and envelop at the input of neural network as detailed above leads to a consideration of all the required inputs to apply pre-distortion. To this end, the closed form solution when the neural network with phase compensated input is considered and envelop terms with the conventional model-based approach are compared. A conventional model-based approach is called GMP (Generalized memory polynomial). The GMP model with non-linear order P, memory length M and cross-length G is formulated as below:

$$u ( n ) = {\sum }_{p = 0}^{P} {\sum }_{m = 0}^{M} {α}_{p , m} ( {X}_{I} ( n - m ) + {jX}_{Q} ( n - m ) ) {\vert x ( n - m ) \vert}^{p} + {\sum }_{p = 1}^{P} {\sum }_{m = 0}^{M} {\sum }_{g = 0}^{G} {b}_{pmg} ( {X}_{I} ( n - m ) + {jX}_{Q} ( n - m ) ) {\vert x ( n - m - g ) \vert}^{p}$$

Where X_{I}(n) and X_{Q}(n) are the real and imaginary parts of the phase compensated input respectively (as detailed above). α_{p,m}, b_{pmg} and c_{pmg} are the model parameters. Note that in a more generic formulation, only odd terms may be considered.

A GMP based DPD model may be linear on the model parameters. This means that the GMP based DPD model may be written as a weighted sum of non-linear functions. Those non-linear functions are referred to basis functions, for example in the equation above where αₚₘ and b_{pmg} are linear parameters and the remaining part denoted as (X_{I}(n−m)+|X_{Q}(n−m))|x(n−m)|^{P} is basis function. As GMP based DPD module may be written as linear combination of basis functions and parameters, when hardware imperfections are present, applying some changes in basis function and recomputing parameters may be straight forward.

Getting a closed form function for neural networks to get a better design is complex (at least for non-shallow neural networks) due to the presence of non-linear activation functions in hidden layers that brings complexity to derivation of the closed forms. A non-shallow neural network is a neural network with more than one hidden layer. However, there are may similarities between GMP models and a non-shallow neural network that provide insight to the functionality of neural network-based models through a comparison with the GMP models.

A feed forward neural network itself for two hidden consecutive layers may be formulated as below:

$${u}_{k} ( {x}_{i} , w ) = σ ( {\sum }_{j = 1}^{D} {w}_{k , j}^{( 2 )} h ( {\sum }_{i = 1}^{L} {w}_{ji}^{( 1 )} {x}_{i} + {w}_{j 0}^{( 1 )} ) + {w}_{k , 0}^{( 2 )} )$$

with uₖ(xᵢ,w) being the output at neuron k as a function of inputs and weights from previous layers,

$${w}_{k , j}^{( 2 )} , {w}_{ji}^{( 1 )} , {w}_{j 0}^{( 1 )} , {w}_{k , 0}^{( 2 )}$$

being neural network weights after training, σ,h being non-linear activation functions in the hidden layers, D being the number of neurons in the second layer and xᵢ∈{X_{I}(n), X_{I}(n−1), . . . , X_{I}(n−M), X_{Q}(n), X_{Q}(n−1), . . . , X_{Q}(n−M),|x(n)|, |x(n−1)|, . . . |x(n−M)|, |x(n)|², |x(n−1)|², . . . , |x(n−M)|², . . . , |x(n)|^{P}, |x(n−1)|^{P}, . . . , |x(n−M)|^{P}} being the input from the first layer in our case with M being the considered memory depth and P being non-linearity order. L is the input size of the first layer or number of neurons in the first layer. For example, for Res-ARVTDNN L=2(M+1)(2+p).

When it comes to neural networks, decomposition of neural network based DPD to weighted sum of basis functions may not be straight forward due to their inherent nonlinearity. Therefore, mitigation of hardware imperfections may be even less straight forward than a standard GMP based DPD model. For instance, in the equation above it may be seen that in each node of the first hidden layer after application of activation function, a tensor based weighted sum of the inputs (denoted as xᵢ) is present. There is a replica of such a weighted sum of inputs in each hidden neuron of the first hidden layer. When the signal goes through second and third hidden layer of neural network, this relationship becomes less obvious. Therefore, it is not straight forward if hardware imperfections may be mitigated by application of the modification in input.

Assuming that the non-linear function h is tanh function, expanding this function using a Taylor expansion results in the following common terms between the equations for u(n) and uₖ(xᵢ,w) uₖ(xᵢ,w)=(X_{I}(n)+X_{I}(n)|x(n)|+X_{I}(n)|x(n)|²+ . . . +X_{I}(n)|x(n)|^{P}+X_{I}(n)|x(n−1)|+X_{I}(n)|x(n−1)|²+ . . . +X_{I}(n)|x(n−1)|^{P}+X_{I}(n)|x(n−2)|+X_{I}(n)|x(n−2)|²+ . . . +X_{I}(n)|x(n−2)|^{P}+ . . . +X_{I}(n)|x(n−M)|+X_{I}(n)|x(n−M)|²+ . . . +X_{I}(n)|x(n−M)|^{P}+X_{Q}(n)+X_{Q}(n)|x(n)|+X_{Q}(n)|x(n)|²+ . . . +X_{Q}(n)|x(n)|^{P}+X_{Q}(n)|x(n−1)|+X_{Q}(n)|x(n−1)|²+ . . . +X_{Q}(n)|x(n−1)|^{P}+X_{Q}(n)|x(n−2)|+X_{Q}(n)|x(n−2)|²+ . . . +X_{Q}(n)|x(n−2)|^{P}+ . . . +X_{Q}(n)|x(n−M)|+X_{Q}(n)|x(n−M)|²+ . . . +X_{Q}(n)|x(n−M)|^{P}+Other terms)

From the above, linear terms, non-linear term, lagging cross terms and phase compensated inputs of GMP are all included already in the second layer of the neural networks and first neuron. Thus, neural network-based pre-distorter has all the elements to characterize phase compensated pre-distorter. Considering the next layers and corresponding non-linearities, it may be seen that the neural network inputs may generate more rich functions in the hidden layers compared to the baseline GMP. Accordingly, the equation above demonstrates that in the hidden layer of neural network there is a richer combination of basis functions and decomposition to the weighted sum of linear functions is not straightforward.

Herein, it is assumed that activation function is tanh. When other non-linear activation functions are used, similar observations may be derived that are not shown here.

The neural network-based method of the present embodiments in comparison with GMP-based method benefits from the possibility for pre-training the model across wide range of conditions. The generalization capability of the neural networks enables the method to perform the expected task, e.g., PA linearization, even under circumstances for which the model has not been trained for. Hence, the requirements for real-time adjustments of the model parameters may be relaxed for neural network-based method compared to the GMP-based approaches.

Further, for the case of GMP the limited set of linear parameters gives less flexibility for re-training compared to neural networks. During the re-training of GMP, a smaller number of parameters corresponding to smaller set of features (e.g. aging, temperature, traffic, and hardware imperfections) may be updated.

In the case of neural networks, having more parameters gives much more flexibility for re-training. For instance, the network may be re-trained to get parameters to follow a cluster of features (e.g. aging, temperature, traffic, and hardware imperfections) all together. This flexibility allows a user to rely more on re-training instead of pre-defined tables and get the best match to the environment and use case. For instance, this feature is valuable for Gallium Nitride (GaN) power amplifiers that are sensitive to temperature and traffic.

By way of example, memory impact is present when output of the power amplifier at one time instant is the function of the input at the same time instant and previous time instants. A GMP model that deploys a simple input/output relationship even with a memory as input may not fully model this type of imperfection that are mostly present for very high bandwidths. In contrast, in the case of neural networks, this feature may be captured for example by using some type of neural networks (such as Long-Short Term Memory (LSTM) or Bidirectional Long-Short Term Memory (BI-LSTM)) or deploying feedback that may capture the memory in a more efficient way.

Further, in the transmitter path several layers of imperfections may be present due to the presence of the devices, for example filters, mixers, a PAs. In this case, a neural network that has a more redundant structure of basis functions due to the presence of hidden layers could capture these imperfections all together. In contrast, in the case of GMP with one set of basis function, more tuning is needed, and the overall structure may not be stable.

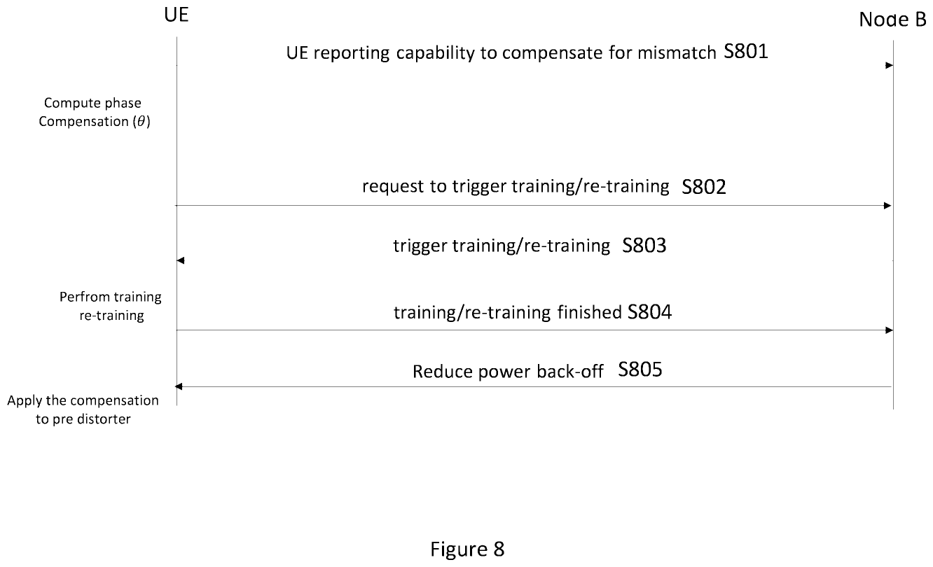

FIG. 8 is a signal diagram illustrating a flow of information in a system, in accordance with the present embodiments. When the signal to be amplified is an uplink signal and when the DPD is used in a user equipment (UE), a signaling procedure as depicted in FIG. 6 may be used as a standard procedure.

For example, the user equipment may report its capability to compensate for the mismatch (Step S801). Alternatively or additionally, the user equipment may report its capability to adapt for the power backoff. The user equipment may also compute the phase mismatch as detailed above. The user equipment may then send a request to base station, for example when the mismatch is larger than a threshold value (Step S802). The user equipment may receive a signal from base station to trigger training, re-training (Step S803) and the user equipment may perform training/re-training as requested and send a signal to the base station once the training/re-training is finished (Step S804). The user equipment may then apply the compensation to the uplink transmit signal. Finally, the user equipment may receive a signal from base station to reduce the power backoff and may accordingly reduce the power back-off, for example to adjust to an out-of-band emission requirement (Step S805).

When transmit signal is a downlink signal and when digital pre distorter is used in base station, a process corresponding to that for a UE may be used. For example, the base station may measure time and phase mismatch, and trigger training/re-training for example when time and phase mismatch is larger than a threshold and/or on the same occasion as a self-recovery. The base station may then perform training/re-training and apply the compensation to the transmit signal after training of pre distorter. Accordingly, the power back-off may be reduced to adjust to an out-of-band emission requirement on base station.

The following simulations are used as proof of concept to show that when a post-inverse and consequently pre-distortion model is time aligned with the peaks of correlation between input and output of power amplifier, better performance and lower computational complexity may be achieved compared to the case where pre-distortion is not time aligned with power amplifier most significant input/output cross-correlation values.

As discussed earlier, the peaks of cross correlation between the input and output of the power amplifier coming from the data set would indicate the most significant delay taps to be considered and the time lags between the two signals that results the peaks.

By way of example, the peak of cross correlation may happen at first- and last-time lags, corresponding to time-alignment value=0 and value=−1 respectively in the resulted cross correlation. Indeed, the time-alignment value=−1 indicates the maximum of cross correlation value followed by time-alignment value=0 that indicates the second largest cross correlation value. Therefore, shifting the input of power amplifier by −1 and taking this into account in the resulted signal as the input for the post inverse and pre distorter model to capture the most important components will give the best performance. This is equivalent of applying time-alignment between input and output of power amplifier.

Firstly, Virtual Power Amplifier (V-PA) model is modelled as the first step before modelling the post-inverse and neural network-based pre distorter. It's desired to choose the neural network V-PA model as the one that performs best on the data set as the overall performance would depend on the V-PA performance. Indeed, V-PA performance determines the lower band of the achievable performance in the cascade of pre distorter and V-PA. The simulations show the best performance for V-PA when Residual ARVTDNN neural network model (described in section 2.2) is considered. Therefore, this model has been selected as the one used for V-PA modelling.

The data characteristics are summarized in Table 2:

TABLE 2
Data characteristics for V-PA modelling

| | | Sampling | Carrier | | |
|---|---|---|---|---|---|
| | BW of each | frequency | frequency | Data set size | IBW |
| | band (MHz) | (fₛ) | (f_{c}) - MHz | (samples) | (MHz) |
| Dual | 40:40 | 983040000 | 3.6 × 10\hat{ }9 | 196608 | 200 MHz |
| band | | | | | |

As mentioned, the peaks of cross correlation between input and output of power amplifier in the present example correspond to time-lag value −1 and 0 with −1 being the maximum value. Thus, several sets of tap values are considered for V-PA modeling including m∈{−1,0,1}, m∈{−1, 0, 1, 2} and m∈{0, 1, 2, 3}. The last selected value considers only one peak of cross correlation (with time lag 0). Table 3 shows the simulation assumption used to model the V-PA in a dual band scenario case with IBW=200 MHz and residual ARVTDNN.

TABLE 3
Details of simulation assumption used to model the V-PA in a dual
band scenario case with IBW = 200 MHz and residual ARVTDNN

| Parameter | Network type | dual band | |
|---|---|---|---|
| | Residual | m ∈ {0, 1, . . . , 3} | |
| | ARVTDNN | m ∈ {−1, 0, 1, 2} | |
| | (Residual | m ∈ {−1, 0, 1} | |
| | Augmented | Number of neurons = | |
| | Value Time | [16] | |
| | Delay Neural | Batch-size = 512 | |
| | Network) | Epoch = 500 | |
| | | Aug_env = 4 | |
| | | Hidden layers = 3 | |
| | | Early stopping = No | |
| Activation | | Relu for hidden layer, | |
| function | | linear for output layer | |
| Training | | %35 | |
| portion of | | | |
| data | | | |
| Validation | | %10 of 35% reported | |
| portion of | | above | |
| data | | | |
| Test portion | | %65 | |
| of data | | | |
| Optimizer | | Adam | |
| metric | | mse | |
| Learning | | 0.001 | |
| rate | | | |
| Total data | | 196608 | |
| set size | | | |
| (samples) | | | |
| IBW | | 200 | MHz |
| Fs (sampling | | 983 | MHz |
| frequency) | | | |
| BW-pass of | | 3.2 × 10⁸ | Hz |
| fft filter using | | | |
| hanning | | | |
| window | | | |
| BW-stop of | | 3.25 × 10⁸ | Hz |
| fft filter using | | | |
| hanning | | | |
| window | | | |
| Seed | | Random type | |
| selection | | | |

The output of the V-PA has been filtered out to focus on dual band scenario without loss of generality. No early stopping was used in the evaluations provided in Table 3. In accordance with the discussions above, the next step of present embodiments is to train a given post-inverse model and copy the coefficient to the pre distorter.

Table 4 summarizes the simulation assumptions used for post-distorter and pre distorter. The present example uses a Residual ARVTDNN feed forward neural network architecture. The number of neurons in hidden layers are varied [4, 6, 8, 12, 16] to assess the performance as a function of complexity or number of flops. The present example follows a rule to select the number of neurons not to suffer over-fitting or under-fitting behavior. Consecutive values of delay taps are considered here. Values considered include m∈{−1, 0, 1}, m∈{−1, 0, 1, 2} and m∈{0, 1, 2, 3}. In the first two case time aligning input and output of the post inverse and pre distorter model are considered, further considering the most important taps while in the last case there is no aligning the pre distorter taps with the one from power amplifier largest ones.

TABLE 4
simulation assumptions used for post-distorter and pre distorter

| Parameter | Network type | Two band |
|---|---|---|
| | Residual | m ∈ {0, 1, . . . , 3} |
| | ARVTDNN | m ∈ {−1, 0, 1, 2} |
| | (Residual | m ∈ {−1, 0, 1} |
| | Augmented | Aug_env = 4 |
| | Value Time | |
| | Delay Neural | |
| | Network) | |
| Hidden | | 3 |
| layers | | |
| Number of | | [4, 6, 8, 12, 16] |
| neurons | | |
| considered | | |
| Activation | | Relu for hidden layer, |
| function | | linear for output layer |
| Training | | %35 |
| portion of | | |
| data | | |
| Validation | | %10 of 35% reported |
| portion of | | above |
| data | | |
| Test portion | | %65 |
| of data | | |
| Optimizer | | Adam |
| metric | | mse |
| Learning | | 0.001 |
| rate | | |
| Epochs | | 500 |
| Batch-size | | 512 |
| Total data | | 196608 |
| set size | | |
| (samples) | | |
| IBW | | 200 MHz |
| Fs (sampling | | 983 MHz |
| frequency) | | |

NMSE (Normalized Mean Squared Error) is defined as all-band error (or distortion) in time domain between the PA output signal with gain normalization (y(n)) and pre distorter input signal (x(n)). This may be written as:

$$NMSE = 10 \times {log}_{10} \frac{E [ {\vert y ( n ) - x ( n ) \vert}^{2} ]}{E [ {\vert x ( n ) \vert}^{2} ]}$$

where E is the expectation of the NMSE. E is equivalent to averaging over realizations of the signal, and may be further written as:

$$E [ z ] = \frac{1}{N} {\sum }_{i = 1}^{N} {z}_{i}$$

where N is the number of realizations and zᵢ is the observation number i.

ACLR (Adjacent Channel Leakage power Ratio), denotes the ratio of the filtered mean power centred on the adjacent channel frequency to filtered mean power centred on the assigned channel frequency [Definition from 3GPP (TS 36.141)]. In other words, ACLR evaluates the amount of out-of-band emission. ACLR is measured in dB and is defined using equation below, where Y(f) denotes Fourier transform of PA output signal.

$$ACLR = \frac{{\int }_{adj .} {\vert Y ( f ) \vert}^{2} df}{{\int }_{ch .} {\vert Y ( f ) \vert}^{2} df}$$

The computational complexity is measured in term of floating point (flops) operations standing for number of real multiplications/additions for inference per symbol of feed forward neural network. Number of flops for inference is a key performance indicator.

Number of Flops for different versions of feedforward neural network may be computed as in the following:

$$C = {\sum }_{l = 1}^{L - 1} {D}^{l} {D}^{l + 1} + 2$$

with L being total number of layers known as the depth of neural network, C being the number of flops, and number of neurons in layer 1 denoted by D^{I}. The value of +2 in the equation above captures for the two additions related to identity connection. This term will not appear for non-residual versions of neural networks.

Number of neurons in the input layer for different networks is listed in Table 5:

TABLE 5
Number of neurons in the input layer for different networks

| | Number of neurons |
|---|---|
| Network | in the input layer |
| Res-ARVTDNN | (M + 1) × (2 + p) |
| R2TDNN | (M + 1) × 2 |
| NResNN | (M + 1) × 2 |
| Non-residual ARVTDNN | (M + 1) × (2 + p) |

With p being the value of augmented envelop (denoted as Aug-env in simulation assumptions) and M being the number of considered memory elements or memory taps (e.g., for m∈{−1, 0, 1, 2}, M=4).

For overall complexity computation, when it comes to implementation aspects, the complexity of non-linear elements considered as activation function for hidden layer such as “relu” or “tanh” should be considered.

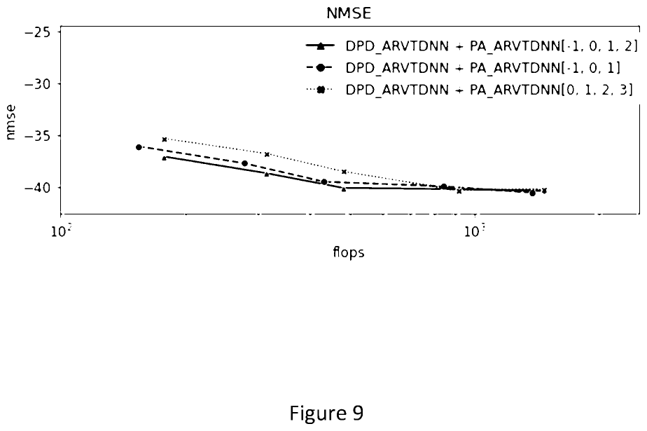

FIG. 9 is a plot demonstrating NMSE versus number of flops (Res-ARVTDNN) using different memory taps. That is, FIG. 9 shows NMSE versus the number of flops obtained from the above simulation assumption. Each marker in the figure corresponds to a specific number of neurons considered in hidden layer.

As discussed previously, in the present example pre distorter taps were aligned with significant taps of power amplifier for some cases (denoted by legend m∈{−1, 0, 1}, m∈{−1, 0, 1, 2}). An additional case was simulated wherein where pre distorter taps are not aligned with that of the actual power amplifier (denoted by legend m∈{0, 1, 2, 3}).

It may be seen from NMSE results that when time-alignment is not performed there is a loss of NMSE of about more than 2 dB for lower number of neurons [4,6,8], when the same number of flops is considered. Best NMSE is obtained when time-alignment for the pre distorter model is performed and all the most significant taps (−1,0) are considered. Considering more taps would increase the computational complexity of the process as it increases the size of input layer. This may improve the performance is some cases as well. This may be observed comparing the case of (m∈{−1, 0, 1}, m∈{−1, 0, 1, 2}).) In present embodiments, input layer configuration may be re-configured across different use cases.

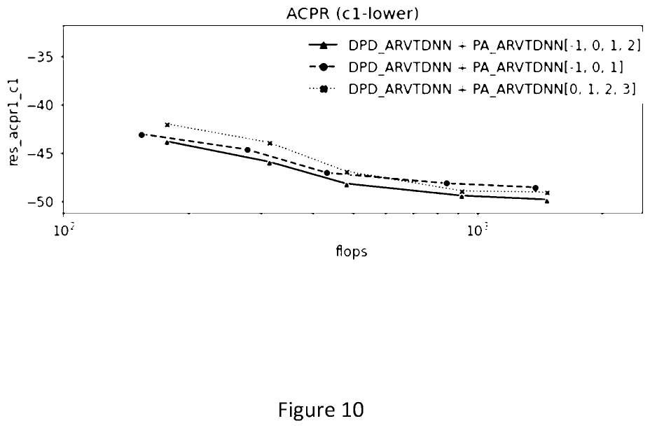

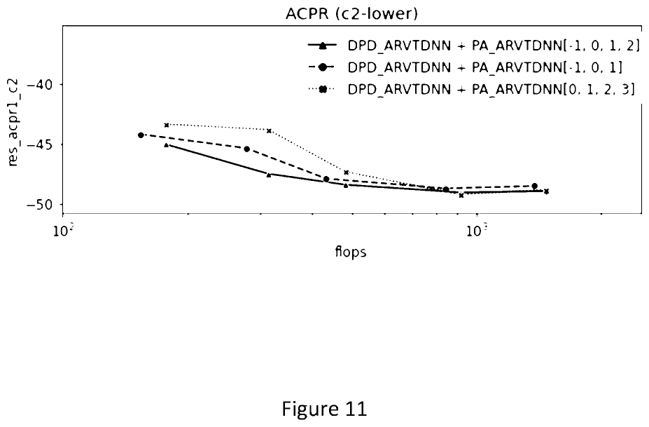

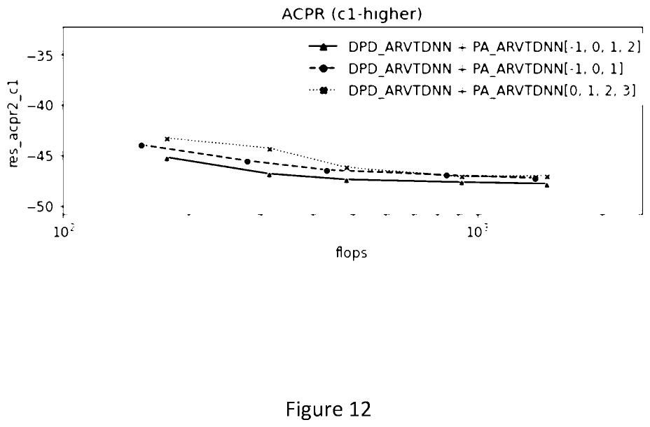

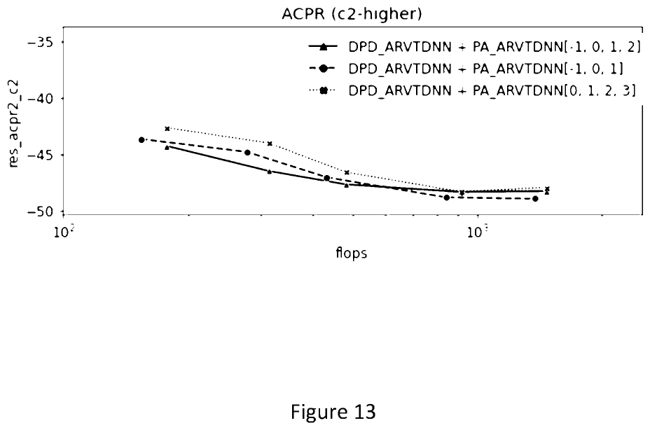

FIG. 10, FIG. 11, FIG. 12, and FIG. 13 show ACPR values for versus the number of flops. That is, FIG. 10 is a plot demonstrating ACPR versus number of flops (Res-ARVTDNN) for lower band and first carrier using different memory taps. FIG. 11 is a plot demonstrating ACPR versus number of flops (Res-ARVTDNN) for lower band second carrier using different memory taps. FIG. 12 is a plot demonstrating ACPR versus the number of flops (Res-ARVTDNN) for upper band first carrier using different memory taps. FIG. 13 is a plot demonstrating ACPR versus the number of flops (Res-ARVTDNN) for upper band second carrier using different memory taps.

Each marker in the figure corresponds to a specific number of neurons considered in hidden layer. As discussed previously, pre distorter taps were aligned with significant taps of power amplifier for some cases (denoted by legend m∈{−1, 0, 1}, m∈{−1, 0, 1, 2}). An additional case was simulated where pre distorter taps are not aligned with that of the actual power amplifier (denoted by legend m∈{0, 1, 2, 3}).

It may be seen from the ACPR results that when time-alignment is not performed there is a loss of NMSE of about more than 2 dB for lower number of neurons [4,6,8], when the same number of flops are considered. Best ACPR is obtained when time-alignment for the pre distorter model is performed, and all the most significant taps are considered. Considering more taps would increase the computational complexity and improve the performance is some cases for example the case of (m∈{−1, 0, 1}, m∈{−1, 0, 1, 2}).) It will be appreciated that examples of the present disclosure may be virtualised, such that the methods and processes described herein may be run in a cloud environment.

The methods of the present disclosure may be implemented in hardware, or as software modules running on one or more processors. The methods may also be carried out according to the instructions of a computer program, and the present disclosure also provides a computer readable medium having stored thereon a program for carrying out any of the methods described herein. A computer program embodying the disclosure may be stored on a computer readable medium, or it could, for example, be in the form of a signal such as a downloadable data signal provided from an Internet website, or it could be in any other form.

In general, the various exemplary embodiments may be implemented in hardware or special purpose circuits, software, logic or any combination thereof. For example, some aspects may be implemented in hardware, while other aspects may be implemented in firmware or software which may be executed by a controller, microprocessor or other computing device, although the disclosure is not limited thereto. While various aspects of the exemplary embodiments of this disclosure may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

As such, it should be appreciated that at least some aspects of the exemplary embodiments of the disclosure may be practiced in various components such as integrated circuit chips and modules. It should thus be appreciated that the exemplary embodiments of this disclosure may be realized in an apparatus that is embodied as an integrated circuit, where the integrated circuit may comprise circuitry (as well as possibly firmware) for embodying at least one or more of a data processor, a digital signal processor, baseband circuitry and radio frequency circuitry that are configurable so as to operate in accordance with the exemplary embodiments of this disclosure.

It should be appreciated that at least some aspects of the exemplary embodiments of the disclosure may be embodied in computer-executable instructions, such as in one or more program modules, executed by one or more computers or other devices. Generally, program modules include routines, programs, objects, components, data structures, etc. that perform particular tasks or implement particular abstract data types when executed by a processor in a computer or other device. The computer executable instructions may be stored on a computer readable medium such as a hard disk, optical disk, removable storage media, solid state memory, RAM, etc. As will be appreciated by one of skill in the art, the function of the program modules may be combined or distributed as desired in various embodiments. In addition, the function may be embodied in whole or in part in firmware or hardware equivalents such as integrated circuits, field programmable gate arrays (FPGA), and the like.

References in the present disclosure to “one embodiment”, “an embodiment” and so on, indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments whether or not explicitly described.

It should be understood that, although the terms “first”, “second” and so on may be used herein to describe various elements, these elements should not be limited by these terms. These terms are only used to distinguish one element from another. For example, a first element could be termed a second element, and similarly, a second element could be termed a first element, without departing from the scope of the disclosure. As used herein, the term “and/or” includes any and all combinations of one or more of the associated listed terms.

The terminology used herein is for the purpose of describing particular embodiments only and is not intended to limit the present disclosure. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components, but do not preclude the presence or addition of one or more other features, elements, components and/or combinations thereof. The terms “connect”, “connects”, “connecting” and/or “connected” used herein cover the direct and/or indirect connection between two elements.

The present disclosure includes any novel feature or combination of features disclosed herein either explicitly or any generalization thereof. Various modifications and adaptations to the foregoing exemplary embodiments of this disclosure may become apparent to those skilled in the relevant arts in view of the foregoing description, when read in conjunction with the accompanying drawings. However, any and all modifications will still fall within the scope of the non-limiting and exemplary embodiments of this disclosure. For the avoidance of doubt, the scope of the disclosure is defined by the claims.

1-44. (canceled)

45. A method for linearization of a power amplifier (PA) output comprising:
training a neural network (NN) of an NN-based Digital Pre-Distortion (DPD) unit using a feedback loop, wherein the feedback loop comprises:
obtaining a training pre-distorter signal, a training PA signal and a training DPD unit signal, wherein the training pre-distorter signal, the training PA signal, and the training DPD unit signal are all associated with each other;
calculating a training signal length using the training PA signal and the training DPD unit signal;
calculating a time shifted signal using the training PA signal and the training signal length;
calculating a phase mismatch between the time shifted signal and the training DPD unit signal;
calculating a compensated pre-distorter signal using the training pre-distorter signal and the phase mismatch; and
training the NN of the NN-based DPD unit using the compensated pre-distorter signal;
wherein the method further comprises:
inputting a signal to be amplified into the NN-based DPD unit;
obtaining a DPD unit signal from the NN-based DPD unit;
inputting the DPD unit signal into the PA; and
obtaining an amplified signal from the PA.

46. The method of claim 45, wherein the training the NN-based DPD unit further comprises:
calculating a DPD coefficient using the training DPD unit signal and the phase mismatch; and
copying the DPD coefficient to the NN-based DPD unit using a post-inverse model.

47. The method of claim 46, wherein the DPD coefficient is calculated using the equation:
$${z}^{′} ( n ) = z ( n ) {e}^{j θ}$$
where z′ is the DPD coefficient, z is the training DPD unit signal, and wherein the compensated pre-distorter signal is calculated using the equation:
$$X ( n ) = ( {x}_{I} ( n ) + j {x}_{Q} ( n ) ) {e}^{j θ}$$
where X is the compensated pre-distorter signal, x_{I}(n) is the real part of the training pre-distorter signal at time n, x_{Q}(n) is the imaginary part of the training pre-distorter signal at time n, θ is the phase shift, and j=√(−1).

48. The method of claim 45, wherein the method further comprises:
calculating a cross correlation between the training PA signal and the training DPD unit signal;
determining a peak of cross correlation using the cross correlation;
calculating the training signal length using the cross correlation;
calculating a shift coefficient using the training signal length and the peak of cross correlation; and
calculating the time shifted signal using the training PA signal and the shift coefficient.

49. The method of claim 48, wherein the cross correlation is calculated using the equation:
$$r = xCorr ( u , y ) = ifft ( fft ( u ) \cdot conj ( fft ( y ) ) )$$
where r is the cross correlation, u is the training DPD unit signal, y is the training PA signal, fft is the fast Fourier transform function, ifft is the inverse fast Fourier transform function, conj is the conjugate function, and · is the dot product function.

50. The method of claim 48, wherein the peak of cross correlation is calculated using the equation:
$$Δ = argmax ( r )$$
where Δ is the peak of cross correlation, argmax is a peak value function, and r is the cross correlation.

51. The method of claim 48, wherein the training signal length is calculated using the equation:
$$N = [ length ( r ) - 1 ] / 2$$
where N is the training signal length, r is the cross correlation, and the length function is the number of elements in the cross correlation.

52. The method of claim 48, wherein the shift coefficient is calculated using the equation:
$$s = N + 1 - Δ$$
where s is the shift coefficient, Δ is the peak of cross correlation, and N is the training signal length.

53. The method of claim 48, wherein the time shifted signal is calculated using the equation:
$${w}_{shift} = circshift ( y , s )$$
wherein w_{shift} is the time shifted signal, y is the training PA signal, s is the shift coefficient, and the circshift function rotates the elements of the training PA signal by a number of positions equal to the shift coefficient.

54. The method of claim 45, wherein the phase mismatch is calculated using the equation:
$$θ = angle ( {u ( n )}^{*} \cdot {w}_{shift} )$$
wherein θ is the phase mismatch, u(n)* is the complex conjugate of the training DPD unit signal, w_{shift} is the time shifted signal, · is the dot product function and angle is the phase angle function for each element of the dot product function.

55. The method of claim 45, wherein the method further comprises calculating the phase mismatch associated with the signal to be amplified.

56. The method of claim 55, wherein the method further comprises triggering a further training procedure if the phase mismatch associated with the signal to be amplified is above a certain threshold.

57. The method of claim 56, wherein the further training procedure comprises updating existing weights of the neural network using the feedback loop.

58. The method of claim 45, wherein the method further comprises:
filtering the training PA signal to obtain a filtered training PA signal;
calculating the training signal length using the filtered training PA signal; and
calculating the time shifted signal using the filtered training PA signal.

59. The method of claim 59, wherein filtering the training PA signal to obtained a filtered training PA signal comprises filtering the training PA signal using a band-pass filter.

60. The method of claim 45, wherein the method further comprises:
filtering the training DPD unit signal to obtain a filtered training DPD unit signal;
calculating the training signal length using the filtered training DPD signal; and
calculating the phase mismatch using the filtered training DPD signal.

61. The method of claim 45, wherein the feedback loop is repeated until the NN of the NN-based DPD unit reaches a predetermined performance threshold.

62. The method of claim 45, wherein the method is executed by a network apparatus.

63. A non-transitory computer-readable storage medium having stored thereon a computer program comprising instructions configured so as to, when executed on at least one processor, cause the at least one processor to carry out a method in accordance with claim 45.

64. A network apparatus, the network apparatus comprising processing circuitry and a non-transitory machine-readable medium storing instructions for execution by the processing circuitry, whereby the network apparatus is configured to:
train a neural network (NN) of an NN-based Digital Pre-Distortion (DPD) unit using a feedback loop, wherein the feedback loop comprises:
obtaining a training pre-distorter signal, a training PA signal and a training DPD unit signal, wherein the training pre-distorter signal, the training PA signal, and the training DPD unit signal are all associated with each other;
calculating a training signal length using the training PA signal and the training DPD unit signal;
calculating a time shifted signal using the training PA signal and the training signal length;
calculating a phase mismatch between the time shifted signal and the training DPD unit signal;
calculating a compensated pre-distorter signal using the training pre-distorter signal and the phase mismatch; and
training the NN of the NN-based DPD unit using the compensated pre-distorter signal;
wherein the network apparatus is further configured to:
input a signal to be amplified into the NN-based DPD unit;
obtain a DPD unit signal from the NN-based DPD unit;
input the DPD unit signal into the PA; and
obtain an amplified signal from the PA.
